(19) United States
(12) Patent Application Publication
(10) Pub. No.: US 2006/0146508 A1
(43) Pub. Date: Jul. 6, 2006

(54) Low-inductance circuit arrangement

(75) Inventor: Folker Renken, Regensburg (DE)

Correspondence Address: LERNER GREENBERG STEMER LLP, P O BOX 2480, HOLLYWOOD, FL, 33022-2480, US

(73) Assignee: Siemens Aktiengesellschaft

(21) Appl. No.: 10/536,368

(22) PCT Filed: Nov. 19, 2003
(86) PCT No.: PCT/DE03/03822

§ 371 Date: Jan. 24, 2006

(30) Foreign Application Priority Data
Nov. 28, 2002 (DE) 102 55 629.6

(51) Int. Cl. H05K 7/02

(52) U.S. Cl. 361/782

(57) ABSTRACT

The invention relates to a circuit arrangement comprising at lest two electrical components (1, 2) and an energy accumulator (Cd) which are arranged on electroconductive plates (3, 5 and 6) in such a way that current paths which are as short as possible and have a minimal parasitic inductance are created. The inventive circuit arrangement is preferably suitable for a voltage transformer.

The invention relates to a circuit arrangement and a voltage transformer, especially a dc voltage transformer or an ac voltage transformer, especially for a motor vehicle.

A known circuit arrangement (DE 41 10 339 C2) features a smoothing capacitor which is connected electrically to a power supply via plate-type direct current leads. Also connected to the two plate-type supply leads is a switching element which features three semiconductor switches. This produces a low-inductance and heat-conducting circuit arrangement in the area of the plate-type supply lead. Because of parasitic inductances of the electrical supply leads to the semiconductor switches and the capacitor however switching losses and overvoltages still occur in this area.

The object of the invention is to create a circuit arrangement which, as a result of its layout, allows simple and low-inductance connection of electronic components to an energy accumulator.

This object is achieved by a circuit arrangement with the features of patent claim 1.

The circuit arrangement features three electrically conducting plates at least partly electrically isolated from each other, a first electrical component and a second electrical component. These components are unpackaged components.

The first and the second plate are separated by an isolator and arranged layered above one another. The first electrical component is arranged in a cutout of the first plate and electrically connected by a first terminal to the second plate. A second terminal of the first electrical component is electrically connected to the third plate.

The second electrical component is also electrically connected with a first terminal to the third plate. A second terminal of the second electrical component is electrically connected to the first plate.

The first or the third plate are embodied to serve as carriers for the first electrical component or the second electrical component.

Furthermore the circuit arrangement features an energy accumulator which is arranged so that it is electrically connected to the first plate on one side and it is electrically connected to the second plate on the other side.

The second and the third plate thus simultaneously serve as carrier and as electrical supply lead for the first and the second electrical component. The first electrical component is attached to the second plate such that it is simultaneously connected mechanically and electrically to the latter. In the same way, the second electrical component is connected electrically and mechanically to the third plate.

As a result of the inventive layout of the circuit arrangement the parasitic inductances of the supply leads from the energy accumulator to the components are reduced by constructing a current path which is as short as possible and additionally routing the current via plate-type, good electrical conductors with a minimal parasitic inductance. The inductances of the supply leads from the energy accumulator to the components are also almost the same size because of the design of the circuit, which achieves an advantageous symmetrical distribution of the inductances.

Contacting over a large area enables the contact resistance between the second plate and the first electrical component or the third plate and the second electrical component to be reduced. At the same time the heat generated during operation as a result of heat dissipation can be efficiently removed at the relevant plate.

Advantageous embodiments of the invention are described in the subclaims.

The electrical and mechanical connection between the components and the plates can for example be made by a soldered connection or by an adhesive with good electrical and thermal conducting properties. This obtains a good electrical and thermal connection to the plate.

The electrical connections can be embodied as bond connections.

The electrical components of the circuit arrangement preferably include power semiconductor components, such as bipolar transistors, MOSFET transistors, IGBTs, diodes, thyristors or TRIACs.

The first, the second and the third plate can be embodied as metal plates, for example as copper plates or as electrical printed circuit boards.

The circuit arrangement can take the form of a voltage transformer for example. In this arrangement a series circuit of two electrical components forms a half-bridge in each case.

Such a circuit arrangement can be used as a voltage transformer in an integrated starter generator for a motor vehicle.

A number of exemplary embodiments of the invention are explained below on the basis of the schematic figures. The figures show:

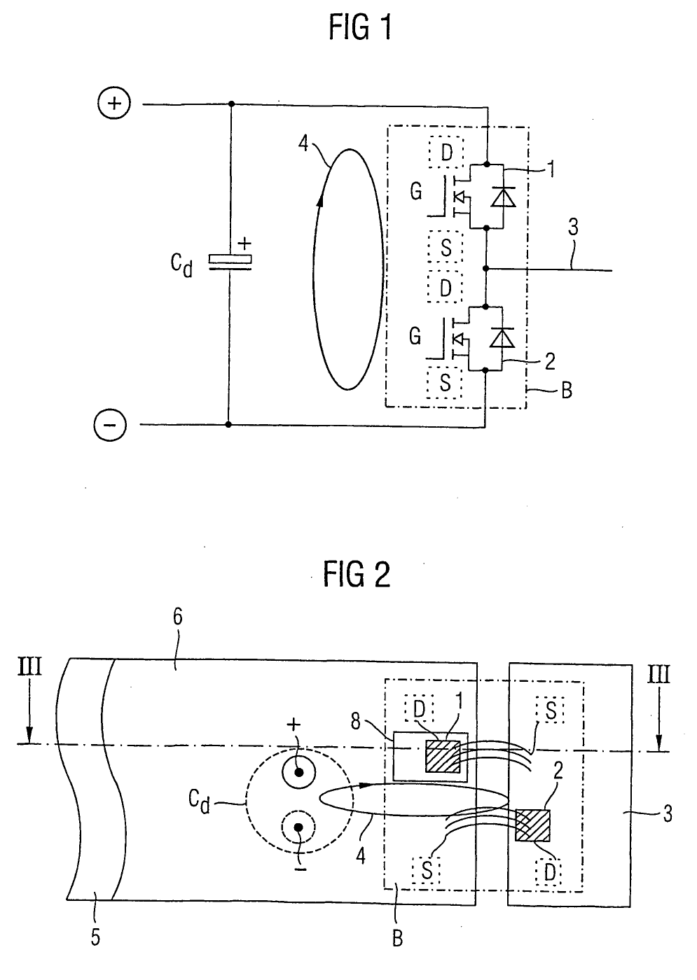

FIG. 1 a circuit arrangement of a first exemplary embodiment of a circuit in accordance with the invention,

FIG. 2 a view from above of the first exemplary embodiment of the circuit arrangement according to FIG. 1,

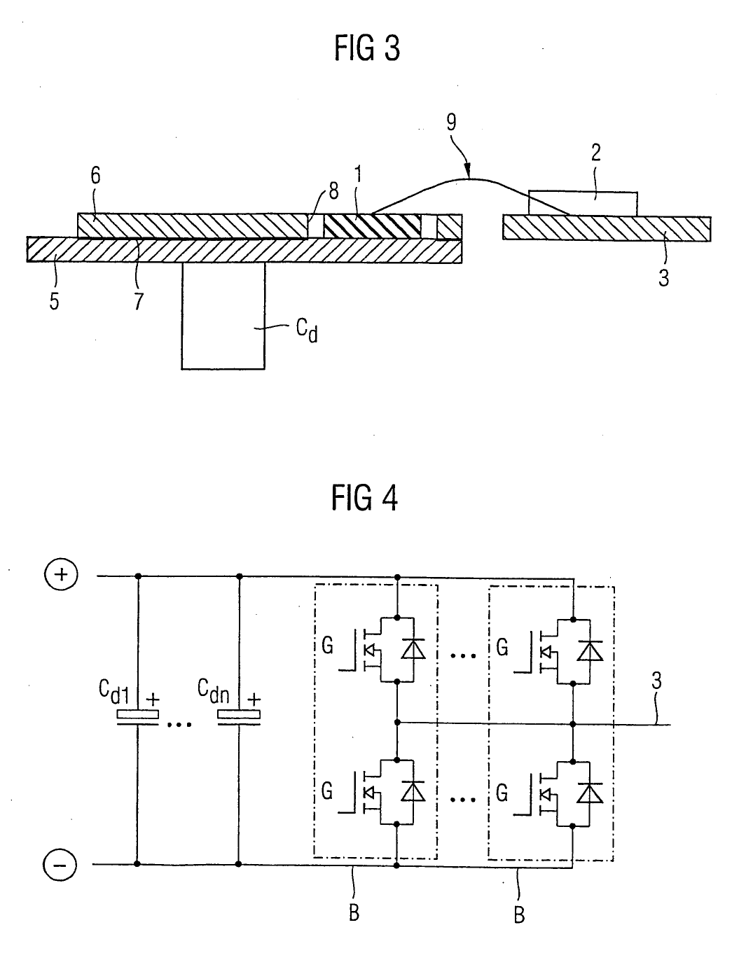

FIG. 3 a cross section through the first exemplary embodiment of the circuit arrangement along the line III-III in FIG. 2,

FIG. 4 a further circuit arrangement of an exemplary embodiment and

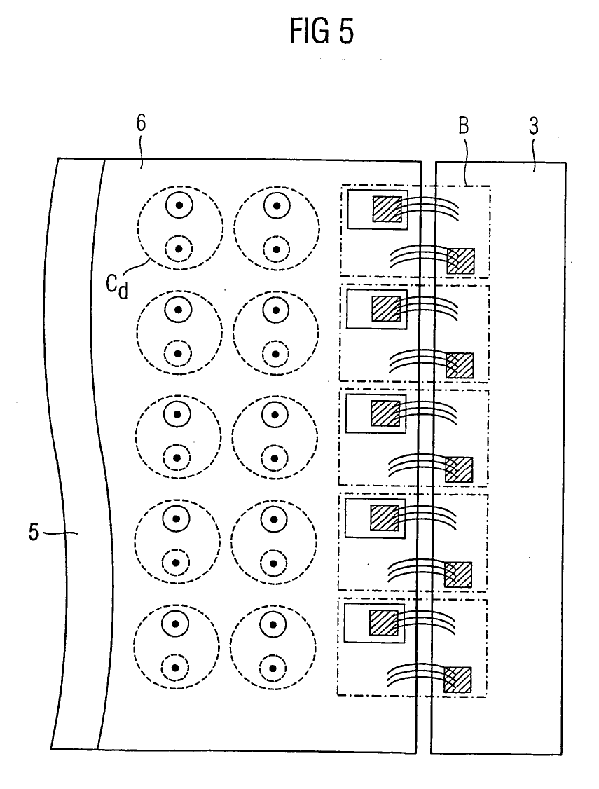

FIG. 5 a view from above of the second exemplary embodiment of the circuit arrangement.

FIG. 1 shows a circuit arrangement in accordance with the invention, featuring a first component, a second component and an energy accumulator C_{d}. The components here are the circuit elements 1 and 2 which are embodied as field effect components. The circuit elements 1 and 2 each feature a Drain [D], a Source [S] and a Gate terminal [G].

The energy accumulator C_{d} is electrically connected to the positive supply voltage on one side and to ground on the other side.

The first circuit element 1 is electrically connected with its Drain terminal [D] to the positive supply voltage and with its Source terminal [S] to the Drain terminal [D] of the second circuit element. The Source terminal [S] of the second circuit element is electrically connected to ground. The circuit elements are thus connected in series to one another and in parallel to the energy accumulator and form a bridge element B.

An output 3 is arranged between the Source terminal of the first circuit element 1 and the Drain terminal of the second circuit element 2.

The parasitic inductances of the circuit indicated as mesh 4 have a negative effect on the switching behavior of the circuit arrangement. These are thus reduced by the geometrical layout of the circuit arrangement and distributed as symmetrically as possible in this mesh 4.

The Gate terminals [G] of the two circuit elements 1 and 2 are connected electrically to a control unit not shown in the diagram and are controlled by this unit.

FIG. 2 shows a view from above of the first exemplary embodiment of the inventive circuit arrangement. The circuit arrangement features a first and a second plate, here a first copper plate 6 which is electrically connected to ground and a second copper plate 5 which is electrically connected to the supply voltage of the circuit arrangement. The two copper plates 5 and 6 are arranged in layers above one another, electrically isolated by an isolating layer 7, for example a foil. The energy accumulator C_{d} is arranged here on the underside of the second copper plate 5 and electrically connected on one side to the first copper plate 6 and on the other side to the second copper plate 5 (cf. FIG. 3).

The electrical connections to the energy accumulator C_{d} are preferably made by welding.

Further the first copper plate 6 features a cutout 8, in the area of which the first electrical component, here the first circuit element 1, is connected electrically and mechanically with its Drain terminal to the second copper plate 5. The surface opposite this mounting surface features the Source terminal and the Gate terminal of the first circuit element 1.

The Source terminal is electrically connected via bond connections 9 with a third plate, here also a copper plate 3, which represents the output. This third plate is arranged here for example as close as possible to the stack consisting of the first and the second plate 6 and 5.

The second circuit element 2 is also electrically and mechanically connected with its Drain terminal to the third copper plate 3. The surface opposite the mounting surface here also features the Source and the Gate terminal. As with the first circuit element 1, the Gate terminal is electrically connected to the control unit not shown in the diagram. The control unit can for example be arranged above the first plate 6 and can be electrically connected via a bond connection not shown in the diagram to the Gate terminal. The Source terminal is electrically connected via bond connections 9 with the first copper plate 6 and thereby with ground.

The section shown in FIG. 3 through the circuit arrangement again illustrates the arrangement of the first and the second copper plate 5 which are separated from one another by an isolation layer 7. This figure also shows how the first electrical component 1 is arranged on the second plate 5 in a cutout 8 of the first plate 6 The energy accumulator C_{d} is arranged here below the second plate 5.

FIG. 4 shows a circuit arrangement of a second exemplary embodiment. Here a number of half bridges B—consisting of two components connected in series—and energy accumulator C_{d} are connected in parallel. Thus the parallel-connected half bridges B are linked with around the same parasitic inductances to the energy accumulator C_{d}.

FIG. 5 shows a view from above of a circuit arrangement according to the second exemplary embodiment.

The components shown in this figure are unpackaged integrated circuits (IC), connected by bond wire connections 9 to their circuit environment. Their unpackaged form in conjunction with the connection technology employed achieves a significant space saving.

Because of their thermal loading capability the electrically-isolated plates are frequently designed in hybrid technology. The outstanding feature of this technology is high load bearing capability small footprint and very high reliability under demanding conditions of use.

In hybrid technology conductor track structures, isolation layers and resistors are printed onto substrates using the screen printing method. The most widely-used substrate material is aluminum oxide. A laser is used to cut or make holes for through-contacting.

In this way a number of conductor track layers can be arranged one above the other and connected by the corresponding through-contacting windows (vias) to each other in the isolation layers.

Hybrid technology makes it possible to achieve a high density of conductor tracks on small surfaces. The fact that the substrate material used conducts heat very well also makes possible good dissipation of the heat dissipation power frequently generated.

1-6. (canceled)

7. A circuit configuration, comprising:
three mutually insulated, electrically conducting plates, said plates including a first plate and a second plate disposed above one another, and a third plate, said first plate having a cutout formed therein;
a first unpackaged electrical component disposed in said cutout and on said second plate, said first electrical component being electrically and mechanically connected to said second plate and being electrically connected to said third plate;
a second unpackaged electrical component disposed on said third plate, said second electrical component being electrically and mechanically connected to said third plate and being electrically connected to said first plate; and
an energy accumulator electrically connected to said first plate and to said second plate, wherein short paths and a plate cross section of said plates defines a low-inductance, symmetrical electrical connection between said energy accumulator and said first and second components.

8. The circuit configuration according to claim 7, wherein at least one of said first and second electrical components contains an electrical circuit element.

9. The circuit configuration according to claim 7, wherein at least one of said three plates is a copper plate.

10. The circuit configuration according to claim 7, wherein at least one of said three plates contains copper.

11. The circuit configuration according to claim 7, wherein said energy accumulator is welded to at least one of said first and second plates.

12. The circuit configuration according to claim 7, which comprises an amount of electrically-conductive adhesive electrically and mechanically connecting at least one of said first and second electrical components to the respective said second and third plate.

13. A voltage transformer having at least one circuit configuration according to claim 7.

14. A voltage transformer, comprising a plurality of circuit configurations according to claim 7 sharing a common first plate, a common second plate, and a common third plate.
